(19) United States
(12) Patent Application Publication
(10) Pub. No.: US 2024/0404798 A1
(43) Pub. Date: Dec. 5, 2024

(54) HIGH POWER ELECTROSTATIC CHUCK WITH FEATURES PREVENTING HE HOLE LIGHT-UP/ARCING

(71) Applicant: Lam Research Corporation, Fremont, CA (US)

(72) Inventors: Alexander MATYUSHKIN, San Jose, CA (US); Keith COMENDANT, Fremont, CA (US); Darrell EHRLICH, San Jose, CA (US); Eric SAMULON, Oakland, CA (US)

(21) Appl. No.: 18/800,410

(22) Filed: Aug. 12, 2024

Related U.S. Application Data
(63) Continuation of application No. 17/281,183, filed on Mar. 29, 2021.
(60) Provisional application No. 62/754,308, filed on Nov. 1, 2018.

(51) Int. Cl. H01J 37/32; H01L 21/683

(52) U.S. Cl. CPC H01J 37/32724; H01L 21/6833

(57) ABSTRACT

A spark suppression apparatus for a helium line in an electrostatic chuck in a plasma processing chamber is provided. The spark suppression apparatus comprises a dielectric multilumen plug in the helium line, wherein the dielectric multilumen plug has a plurality of lumens, wherein the plurality of lumens are numbered between 30 to 100,000 lumens and have a width of between 1 micron and 200 microns.

### CROSS REFERENCE TO RELATED APPLICATION

This application is a continuation of U.S. application Ser. No. 17/281,183 filed on Mar. 29, 2021, which is a 371 of International Application No. PCT/US2019/058626 filed on Oct. 29, 2019, which claims the benefit of priority of U.S. Application No. 62/754,308, filed on Nov. 1, 2018, which is incorporated herein by reference for all purposes.

### BACKGROUND

The disclosure relates to an apparatus for processing substrates. More specifically the disclosure relates to an apparatus for plasma processing substrates.

In various plasma processing chambers, helium (He) is flowed to a backside of a substrate on an electrostatic chuck (ESC) in order to provide temperature control. Radio frequency (RF) power used for forming a plasma may cause a secondary plasma light-up in the ESC cavities due to high voltage associated with plasma formation. The light-up would promote arcing between any two surfaces with a high electric potential difference between them. Such arcing will cause damage to the ESC.

### SUMMARY

To achieve the foregoing and in accordance with the purpose of the present disclosure, a spark suppression apparatus for a helium line in an electrostatic chuck in a plasma processing chamber is provided. The spark suppression apparatus comprises a dielectric multilumen plug in the helium line, wherein the dielectric multilumen plug has a plurality of lumens, wherein the plurality of lumens are numbered between 30 to 100,000 lumens and have a width of between 1 micron and 200 microns.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic cross-sectional view of a spark suppression apparatus in part of an electrostatic chuck (ESC) that may be used in an embodiment.

FIG. 2 is a schematic cross-sectional view of a spark suppression apparatus in part of an ESC that may be used in another embodiment.

FIG. 3 is a schematic cross-sectional view of a spark suppression apparatus in part of an ESC that may be used in another embodiment.

FIG. 4 is a schematic cross-sectional view of a spark suppression apparatus in part of an ESC that may be used in another embodiment.

FIG. 5 is a schematic cross-sectional view of a spark suppression apparatus in part of an ESC that may be used in another embodiment.

FIG. 6 is a schematic cross-sectional view of a spark suppression apparatus in part of an ESC that may be used in another embodiment.

FIG. 7 is a schematic cross-sectional view of a spark suppression apparatus in part of an ESC that may be used in another embodiment.

FIG. 8 is a schematic cross-sectional view of a spark suppression apparatus in part of an ESC that may be used in another embodiment.

FIG. 9 is a schematic cross-sectional view of a spark suppression apparatus in part of an ESC that may be used in another embodiment.

FIG. 10 is a schematic view of a processing chamber that may be used in an embodiment.

### DETAILED DESCRIPTION OF THE EMBODIMENTS

The present disclosure will now be described in detail with reference to a few embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

New semiconductor manufacturing processes require very high RF power plasmas. Increasing RF power causes an increase in RF currents and total voltages applied to the Electrostatic Chuck (ESC-wafer susceptor). At the same time, new plasma etch processes require significantly lower RF frequencies (e.g. 2 MHZ, 400 kHz, or lower) than previously required. Low RF frequencies cause an additional increase in RF voltage applied across ESC ceramic. High voltage applied across ceramic may cause electrical discharge (arcing) between a wafer and a baseplate or ignition (light-up) of heat transfer gas (e.g. He) in the gas supplying holes. Arcing of the ESC usually causes catastrophic destruction of the part accompanied by wafer destruction, possible damage to other chamber components, and manufacturing process interruption. In the case of the heat transfer gas light-up, ESC destruction could be either catastrophic or could slowly develop affecting multiple wafers with semiconductor device damage, being detected only at much later steps of the manufacturing process. In both cases, ESC failure causes significant loss in wafer production and manufacturer's revenue.

For low-voltage applications, it is common to use straight holes in a ceramic plate with ceramic sleeves in baseplates opposing holes in the ceramic plate and preventing direct line of sight. For mid-low voltage applications, ceramic sleeves in baseplates are replaced with porous plugs providing a higher withstand voltage than ceramic sleeves. For mid-voltage applications, porous plugs are inserted in the ceramic plate, in addition to the sleeves in the baseplate. Further breakdown voltage improvement requires new solutions.

An embodiment provides a solution for ESC arcing and He light-up problems by introducing plugs (made of ceramic material, e.g., alumina Al₂O₃ or aluminum nitride AIN), with small (diameter 0.1-100 micrometers) openings into He holes. The plugs compartmentalize the He hole volume into smaller micro-volumes that limit light-up probability by reducing the number of charged particles' collisions and prevent line of sight between a wafer and metal parts of the chuck below the top ceramic plate while ensuring needed He flow through the holes for the wafer backside cooling.

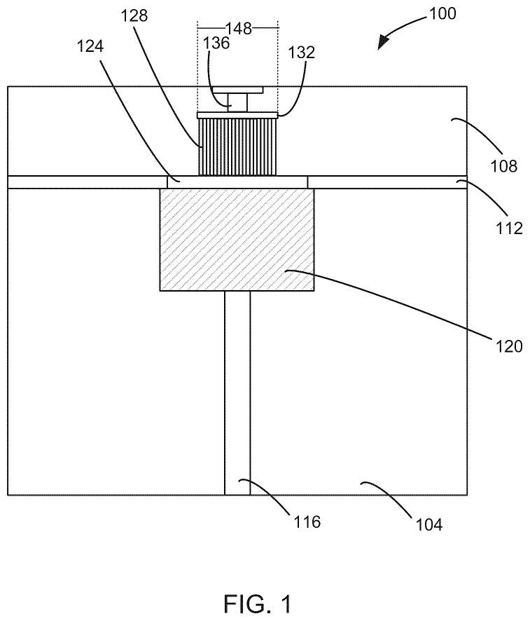

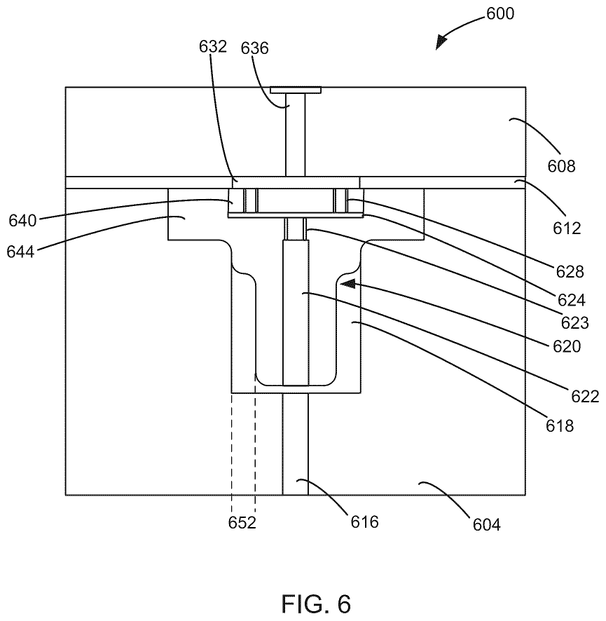

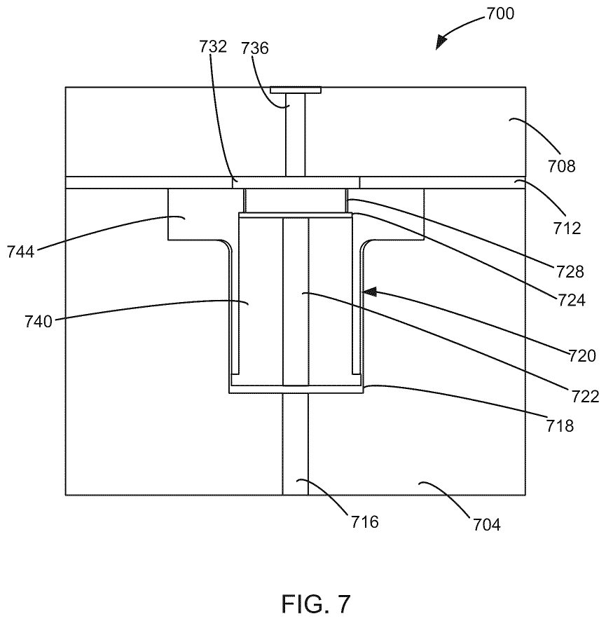

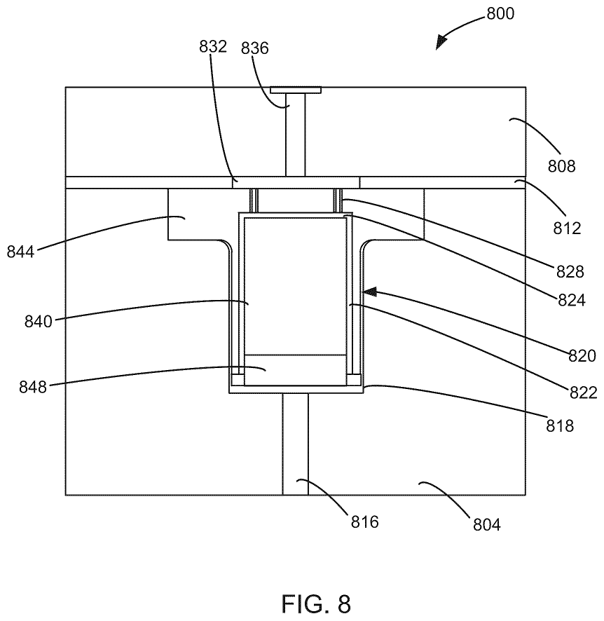

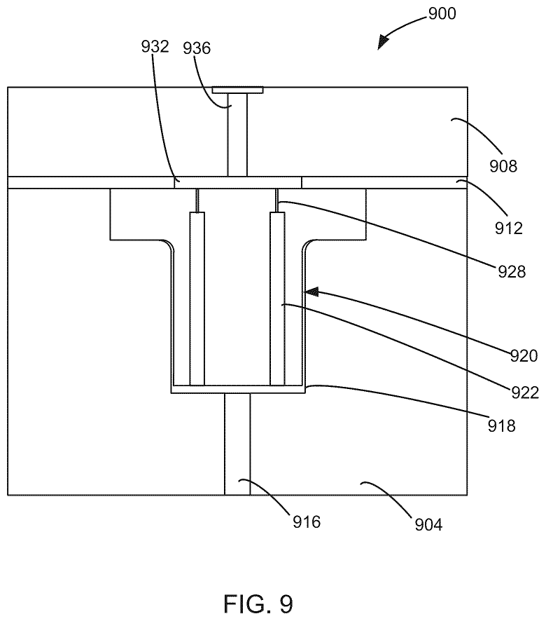

To facilitate understanding, FIG. 1 is a schematic cross-sectional view of a spark suppression apparatus in part of an electrostatic chuck (ESC) 100 that may be used in an embodiment. In this embodiment, the ESC 100 comprises a base plate 104 bonded to a ceramic plate 108 by a bond layer 112. In this embodiment, the base plate 104 is a conductive metal base plate 104, e.g. aluminum. The base plate 104 has a He supply line hole 116. At an output end of the He supply line hole 116 is a porous plug 120. The He supply line hole 116 is on a first side of the porous plug 120. In this embodiment, the porous plug 120 is a porous dielectric plug of ceramic alumina or aluminum nitride with a porosity of 30-50%. In this embodiment, the porous plug 120 has a diameter of 3 to 10 mm that is more than 3 times the characteristic dimension (diameter or width) of the supply line hole 116. In this example, the porous plug 120 extends to the top surface of the base plate 104. The porous plug 120 may have various shapes: e.g., straight as shown in FIG. 1 or with a T-shaped outer envelope as shown in FIG. 6, FIG. 7, FIG. 8, or FIG. 9.

On a second side of the porous plug 120 opposite from the first side of the porous plug is a first plenum 124. The porous plug 120 is on a first side of the first plenum 124. The first plenum 124 is formed in the bond layer 112. On a second side of the first plenum 124, opposite from the first side, is a dielectric multilumen plug 128, made of alumina or aluminum nitride with a plurality of small through holes, and the ceramic plate 108. In this embodiment, the dielectric multilumen plug 128 is bonded to the ceramic plate 108. In this example, the dielectric multilumen plug 128 is a dielectric plug that has 50 to 100,000 lumens, where each lumen has a diameter of between 1 micron and 200 microns. The lumens extend from a first side of the dielectric multilumen plug 128, adjacent to the first plenum 124 to a second side of the dielectric multilumen plug 128 opposite from the first side. The ceramic plate 108 has a thickness between 0.5 mm and 3 mm. The dielectric multilumen plug 128 has a height of between 0.1 mm and 2.5 mm. In this embodiment, the lumens are straight round tubes forming a honeycomb cross-section. Since the lumens are straight and extend across the height of the dielectric multilumen plug 128, the lumens have a length of between 0.1 mm and 2.5 mm. In this embodiment, the dielectric multilumen plug 128 has a diameter of 3 to 5 mm. In this embodiment, the dielectric multilumen plug 128 is made of alumina.

A second plenum 132 is on the second side of the dielectric multilumen plug 128. At least one He hole 136 extends from the second plenum 132 to a surface of the ceramic plate 108. In this example, the at least one He hole 136 has a diameter of between 0.02 to 0.3 mm. In this embodiment, other parts of the ESC 100 has other He supply line holes 116, porous plugs 120, first plenums 124, dielectric multilumen plugs 128, second plenums 132, and He holes 136. At the top surface of the ceramic plate 108, the at least one He hole 136 is shown as being wider, since the wider part may be part of a groove or channel connected between a plurality of He holes 136 at the top surface of the ceramic plate 108. The He supply line hole 116 and the at least one He hole 136 form a helium line, wherein the He supply line hole 116 is a first portion of the He line and the at least one He hole 136 is a second portion of the He line. The second plenum has a width 148. The first plenum 124 has a width. The width of the first plenum 124 is about the same as the diameter of the porous portion of the porous plug 120 and the width 148 of the second plenum 132 is about 80% of the dielectric multilumen plug 128 diameter and at least two times the width of the He supply line hole 116.

This embodiment has been found to reduce arcing. As a result, damage to the wafers has been reduced. In addition, the utilization time/coefficient has been improved. Without being bound by theory, it is believed that providing a large number of thin lumens significantly reduces arcing and allows sufficient He flow. In addition, the porous plug 120 increases the path length that electricity must travel in order to reach a conductive material. This further reduces arcing.

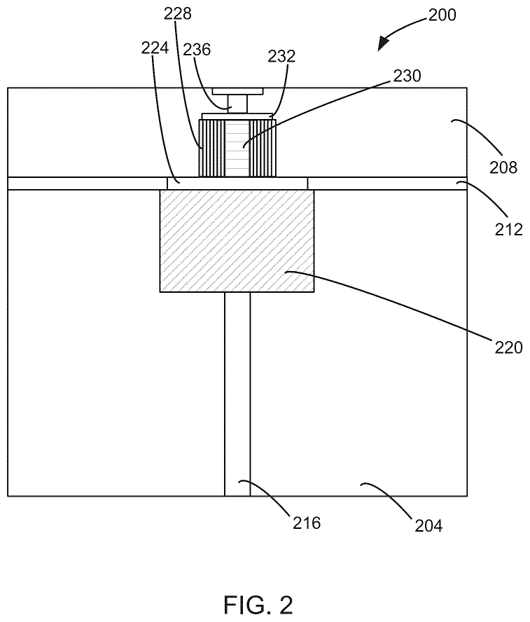

FIG. 2 is a schematic cross-sectional view of a spark suppression apparatus in part of an ESC 200 that may be used in another embodiment. In this embodiment, the ESC 200 comprises a base plate 204 bonded to a ceramic plate 208 by a bond layer 212. In this embodiment, the base plate 204 is a conductive metal base plate 204, e.g. aluminum. The base plate 204 has a He supply line hole 216. At an output end of the He supply line hole 216 is a porous plug 220. The He supply line hole 216 is on a first side of the porous plug 220. In this embodiment, the porous plug 220 is ceramic alumina or aluminum nitride with a porosity of 30-50%. In this embodiment, the porous plug 220 has a diameter that is 3 to 10 mm. In this example, the porous plug 220 extends to a top surface of the base plate 204.

On a second side of the porous plug 220 opposite from the first side of the porous plug 220 is a first plenum 224. The porous plug 220 is on a first side of the first plenum 224. The first plenum 224 is formed in the bond layer 212. On a second side of the first plenum 224, opposite from the first side, is a dielectric multilumen plug 228, made of alumina or aluminum nitride with a plurality of small through holes, and the ceramic plate 208. In this embodiment, the dielectric multilumen plug 228 has a solid core 230 at the center. The dielectric multilumen plug 228 is bonded to the ceramic plate 208. In this example, the dielectric multilumen plug 228 has 30 to 100,000 lumens, where each lumen has a diameter of between 1 micron and 200 microns. The lumens extend from a first side of the dielectric multilumen plug 228, adjacent to the first plenum 224 to a second side of the dielectric multilumen plug 228 opposite from the first side.

A second plenum 232 is on the second side of the dielectric multilumen plug 228. At least one He hole 236 extends from the second plenum 232 to a surface of the ceramic plate 208. In this example, the at least one He hole 236 has a diameter of between 0.05 to 0.3 mm. In this embodiment, the solid core 230 has a diameter greater than the diameter of the at least one He hole 236, such as a cluster of He holes (1-6 holes per location). The solid core 230 has a width and is positioned so as to prevent a line of sight path from the He supply line hole 216 to the at least one He hole 236 through the lumens of the dielectric multilumen plug 228. In this embodiment, further reducing the line of sight of the He flow further reduces arcing. The He supply line hole 216 and the at least one He hole 236 form a helium line, wherein the He supply line hole 216 is a first portion of the He line and the at least one He hole 236 is a second portion of the He line.

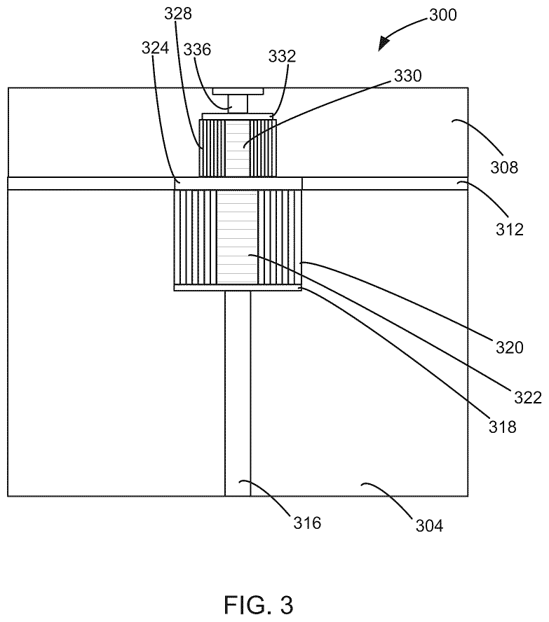

FIG. 3 is a schematic cross-sectional view of a spark suppression apparatus in part of an ESC 300 that may be used in another embodiment. In this embodiment, the ESC 300 comprises a base plate 304 bonded to a ceramic plate 308 by a bond layer 312. In this embodiment, the base plate 304 is a conductive metal base plate 304, e.g. aluminum. The base plate 304 has a He supply line hole 316. At an output end of the He supply line hole 316 is a first plenum 318. The He supply line hole 316 is on a first side of the first plenum 318.

On a second side of the first plenum 318 is a first side of a first dielectric multilumen plug 320 made of alumina or aluminum nitride with a plurality of small through holes. In this embodiment, the first dielectric multilumen plug 320 has a solid core 322 at the center. The first dielectric multilumen plug 320 is bonded to the base plate 304. In this example, the first dielectric multilumen plug 320 has 30 to 100,000 lumens, where each lumen has a diameter of between 1 micron and 200 microns. The lumens extend from a first side of the first dielectric multilumen plug 320, adjacent to the first plenum 318 to a second side of the first dielectric multilumen plug 320 opposite from the first side. In this example, the first dielectric multilumen plug 320 extends to a top surface of the base plate 304.

On a second side of the first dielectric multilumen plug 320 opposite from the first side of the first dielectric multilumen plug 320 is a second plenum 324. The first dielectric multilumen plug 320 is on a first side of the second plenum 324. The second plenum 324 is formed in the bond layer 312. On a second side of the second plenum 324, opposite from the first side, is a second dielectric multilumen plug 328, made of alumina or aluminum nitride with a plurality of small through holes, and the ceramic plate 308. In this embodiment, the second dielectric multilumen plug 328 has a solid core 330 at the center. The second dielectric multilumen plug 328 is bonded to the ceramic plate 308. In this example, the second dielectric multilumen plug 328 has 30 to 100,000 lumens, where each lumen has a diameter of between 1 micron and 200 microns. The lumens extend from a first side of the second dielectric multilumen plug 328, adjacent to the second plenum 324 to a second side of the second dielectric multilumen plug 328 opposite from the first side.

A third plenum 332 is on the second side of the second dielectric multilumen plug 328. At least one He hole 336 extends from the third plenum 332 to a surface of the ceramic plate 308. In this example, the at least one He hole 336 has a diameter of between 0.05 to 0.3 mm. The solid core 330 of the second dielectric multilumen plug 328 has a diameter greater than the diameter of the at least one He hole 336. The solid core 322 of the first dielectric multilumen plug 320 has a diameter that is greater than the diameter of the solid core 330 of the second dielectric multilumen plug 328 and greater than the diameter of the He supply line hole 316. The solid core 322 of the first dielectric multilumen plug 320 and the solid core 330 of the second dielectric multilumen plug 328 each have a width and are positioned so as to prevent a line of sight path from the He supply line hole 316 to the at least one He hole 336 through the lumens of the first dielectric multilumen plug 320 and the second dielectric multilumen plug 328. The lumens allow for an increased He flow. The He supply line hole 316 and the at least one He hole 336 form a helium line, wherein the He supply line hole 316 is a first portion of the He line and the at least one He hole 336 is a second portion of the He line.

In other embodiments, the solid core 322 of the first dielectric multilumen plug 320 and/or the solid core 330 of the second dielectric multilumen plug 328 may be replaced by multiple lumens. Four combinations may be provided. The widths of the solid cores may also vary to add additional embodiments.

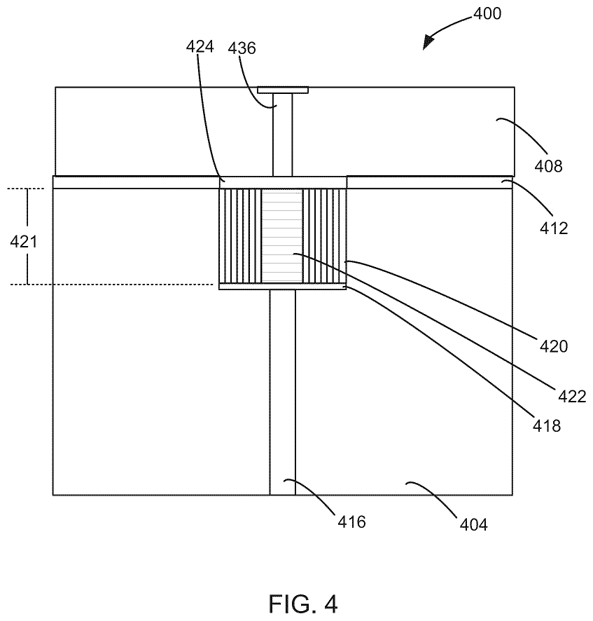

FIG. 4 is a schematic cross-sectional view of a spark suppression apparatus in part of an ESC 400 that may be used in another embodiment. In this embodiment, the ESC 400 comprises a base plate 404 bonded to a ceramic plate 408 by a bond layer 412. In this embodiment, the base plate 404 is a conductive metal base plate 404. The base plate 404 has a He supply line hole 416. At an output end of the He supply line hole 416 is a first plenum 418. The He supply line hole 416 is on a first side of the first plenum 418. On a second side of the first plenum 418 is a first side of a dielectric multilumen plug 420. In this embodiment, the dielectric multilumen plug 420 has a solid core 422 at the center. The dielectric multilumen plug 420 is bonded to the base plate 404. In this example, the dielectric multilumen plug 420 has 30 to 100,000 lumens, where each lumen has a width of between 1 micron and 200 microns. The lumens extend from a first side of the dielectric multilumen plug 420, adjacent to the first plenum 418 to a second side of the dielectric multilumen plug 420 opposite from the first side. In this example, the dielectric multilumen plug 420 extends to a surface of the base plate 404.

On a second side of the dielectric multilumen plug 420 opposite from the first side of the dielectric multilumen plug 420 is a second plenum 424 located in the bond layer 412. The dielectric multilumen plug 420 is on a first side of the second plenum 424.

On a second side of the second plenum 424, opposite from the first side, is at least one He hole 436 that extends from the second plenum 424 to a surface of the ceramic plate 408. In this example, the at least one He hole 436 has a diameter of between 0.03 to 0.3 mm. The solid core 422 of the dielectric multilumen plug 420 has a width and is positioned so as to prevent a line of sight path from the He supply line hole 416 to the at least one He hole 436, such as a cluster of smaller He holes, through the lumens of the dielectric multilumen plug 420.

This embodiment uses only a single plug. By bonding the dielectric multilumen plug 420 in the base plate 404, the dielectric multilumen plug 420 may be larger, allowing for a single plug. In this embodiment, the ceramic plate 408 has a thickness between 0.5 mm and 1.5 mm. The dielectric multilumen plug 420 has a thickness that is much greater than 1 mm. For example, the dielectric multilumen plug 420 has a thickness or height 421 of between 2 mm to 10 mm. In this example, the solid core 422 has a diameter of 1 to 2 mm. The He supply line hole 416 and the at least one He hole 436 form a helium line, wherein the He supply line hole 416 is a first portion of the He line and the at least one He hole 436 is a second portion of the He line.

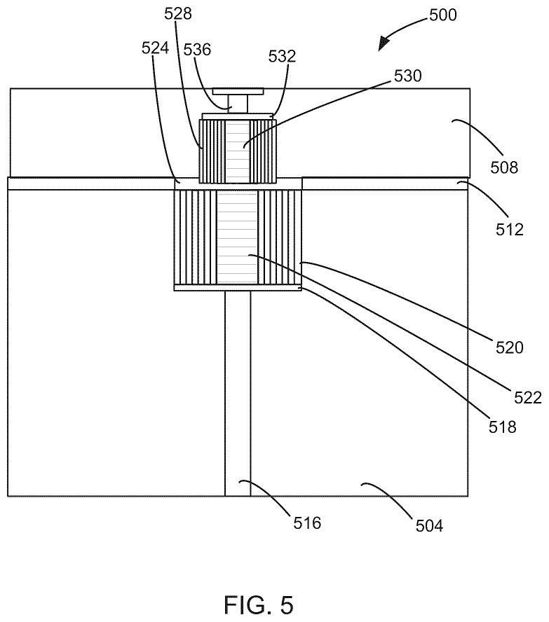

FIG. 5 is a schematic cross-sectional view of a spark suppression apparatus in part of an ESC 500 that may be used in another embodiment. In this embodiment, the ESC 500 comprises a base plate 504 bonded to a ceramic plate 508 by a bond layer 512. In this embodiment, the base plate 504 is a conductive metal base plate 504, e.g. aluminum. The base plate 504 has a He supply line hole 516. At an output end of the He supply line hole 516 is a first plenum 518. The He supply line hole 516 is on a first side of the first plenum 518. On a second side of the first plenum 518 is a first side of a first dielectric multilumen plug 520. In this embodiment, the first dielectric multilumen plug 520 has a solid core 522 at the center. The first dielectric multilumen plug 520 is bonded to the base plate 504. In this example, the first dielectric multilumen plug 520 has 30 to 100,000 lumens, where each lumen has a diameter of between 1 micron and 200 microns. The lumens extend from a first side of the first dielectric multilumen plug 520, adjacent to the first plenum 518 to a second side of the first dielectric multilumen plug 520 opposite from the first side. In this example, the first dielectric multilumen plug 520 extends to a surface of the base plate 504.

On a second side of the first dielectric multilumen plug 520, opposite from the first side of the first dielectric multilumen plug 520, is a second plenum 524. The first dielectric multilumen plug 520 is on a first side of the second plenum 524. The second plenum 524 is formed in the bond layer 512. On a second side of the second plenum 524, opposite from the first side, is a second dielectric multilumen plug 528, made of alumina or aluminum nitride with a plurality of small through holes, and the ceramic plate 508. In this embodiment, the second dielectric multilumen plug 528 has a solid core 530 at the center. The second dielectric multilumen plug 528 is bonded to the ceramic plate 508. In this example, the second dielectric multilumen plug 528 has 30 to 100,000 lumens, where each lumen has a diameter of between 1 micron and 200 microns. The lumens extend from a first side of the second dielectric multilumen plug 528, adjacent to the second plenum 524 to a second side of the second dielectric multilumen plug 528 opposite from the first side. In this embodiment, the second dielectric multilumen plug 528 extends into the second plenum 524. The first side of the second dielectric multilumen plug 528 extends past the surface of the ceramic plate 508 into the layer or region defined by the bond layer 512. In this embodiment, the second dielectric multilumen plug 528 extends into the second plenum 524 to form an overhang of about 50 to 80% of the gap distance, in this specific case: between 0.01 mm to 0.25 mm. In this example, the gap distance is the thickness of the bond layer 512.

A third plenum 532 is on the second side of the second dielectric multilumen plug 528. At least one He hole 536 extends from the third plenum 532 to a surface of the ceramic plate 508. In this example, the at least one He hole 536 has a diameter of between 0.2 to 0.3 mm. The solid core 522 of the first dielectric multilumen plug 520 and the solid core 530 of the second dielectric multilumen plug 528 each have a width and are positioned so as to prevent a line of sight path from the supply line hole 516 to the at least one He hole 536 through the lumens of the first dielectric multilumen plug 520 and the second dielectric multilumen plug 528. The lumens allow for an increased He flow. By extending the second dielectric multilumen plug 528 into the second plenum 524 the height of the second plenum 524 is reduced and arcing is further reduced.

FIG. 6 is a schematic cross-sectional view of a spark suppression apparatus in part of an ESC 600 that may be used in another embodiment. In this embodiment, the ESC 600 comprises a base plate 604 bonded to a ceramic plate 608 by a bond layer 612. In this embodiment, the base plate 604 is a conductive metal base plate 604, e.g. aluminum. The base plate 604 has a He supply line hole 616. At an output end of the He supply line hole 616 is a cavity 618. In this embodiment, the cavity 618 is T-shaped. Partially filling the T-shaped cavity 618 is a dielectric multilumen plug 620. In this embodiment, the dielectric multilumen plug 620 has a central bore 622 with a diameter of 2 to 10 mm extending partially through the center of the dielectric multilumen plug 620. A plurality of He passage holes 623 extends from the central bore 622 to a first plenum 624 within the dielectric multilumen plug 620. In this embodiment, the first plenum 624 has a diameter of between 1 mm to 10 mm and a height of 0.01 to 0.5 mm. In this embodiment, there are between 1 to 300 He passage holes 623 with diameters from 30 microns to 1 mm. A plurality of lumens 628 extend from the first plenum 624 to a second plenum 632 adjacent to a surface of the dielectric multilumen plug 620. In this example, the dielectric multilumen plug 620 has 30 to 500 lumens 628, where each lumen 628 has a diameter of between 30 micron and 150 microns. The plurality of lumens 628 may be placed to form concentric circles. On a second side of the second plenum 632, opposite from the first side, is at least one He hole 636 that extends from the second plenum 632 to a surface of the ceramic plate 608. In this example, the at least one He hole 636 has a diameter of between 0.2 to 0.3 mm. The He supply line hole 616 and the at least one He hole 636 form a helium line, wherein the He supply line hole 616 is a first portion of the He line and the at least one He hole 636 is a second portion of the He line.

The He passage holes 623 and plurality of lumens 628 are located in a way that there is no direct line of sight from the top of the dielectric multilumen plug 620 to its bottom. E.g., if arranged in circles, diameters of circles by the He passage holes 623 are significantly different from diameters of the circles formed by the plurality of lumens 628. In this embodiment, a multilumen core 640 is attached by bonding or ceramic lamination or any other process, to an outer plug 644 to form the dielectric multilumen plug 620. The plurality of lumens 628 is formed to pass through the multilumen core 640, as shown. The bottom of the multilumen core 640 is spaced apart from a top of a central cavity in the outer plug 644 to provide a space forming the first plenum 624. Such a configuration allows for the dielectric multilumen plug 620 to be more easily formed. The dielectric multilumen plug 620 is T-shaped. In this embodiment, the top of the T-shaped dielectric multilumen plug 620 is bonded to the top of the T-shaped cavity 618 of the base plate 604. A gap 652 is between the bottom of the T-shaped dielectric multilumen plug 620 and the T-shaped cavity 618. In this embodiment, the gap is between 0.1 mm and 1 mm.

Electric charges may travel along the surface of T-shaped dielectric multilumen plug 620 and reach the conductive base plate 604. The gap 652 creates a longer surface length from the at least one He hole 636 through the second plenum 632, the plurality of lumens 628, the first plenum 624, the plurality of He passage holes 623, the central bore 622, and the outer surface of the bottom of the outer plug 644 to the base plate 604. The increase in the surface length reduces arcing. Since top of the T-shaped dielectric multilumen plug 620 is bonded to the top of the T-shaped cavity 618 of the base plate 604 with a gas-tight seal, the gap 652 is gas-tight, so that He passing from the He supply line hole 616 flows through the central bore 622, the plurality of He passage holes 623, the first plenum 624, the lumens 628, the second plenum 632 to the He holes 636. This embodiment has been found to prevent arcing at over 50 kW.

FIG. 7 is a schematic cross-sectional view of a spark suppression apparatus in part of an ESC 700 that may be used in another embodiment. In this embodiment, the ESC 700 comprises a base plate 704 bonded to a ceramic plate 708 by a bond layer 712. In this embodiment, the base plate 704 is a conductive metal base plate 704. The base plate 704 has a He supply line hole 716. At an output end of the He supply line hole 716 is a cavity 718. In this embodiment, the cavity 718 is T-shaped. Partially filling the cavity 718 is a dielectric multilumen plug 720. In this embodiment, the dielectric multilumen plug 720 has a central core 740 with a center bore 722 with a diameter of 2 to 10 mm extending partially through the center of the dielectric multilumen plug 720 to a first plenum 724 within the dielectric multilumen plug 720. A plurality of lumens 728 extends from the first plenum 724 to a second plenum 732 adjacent to a surface of the dielectric multilumen plug 720. In this example, the dielectric multilumen plug 720 has 30 to 500 lumens 728, where each lumen 728 has a diameter of between 1 micron and 150 microns. The plurality of lumens 728 may be placed to form concentric circles. All lumens 728 must be located away from the center bore 722 to avoid a direct line of sight from the top of the dielectric multilumen plug 720 to its bottom. On a second side of the second plenum 732, opposite from the first side, is at least one He hole 736 that extends from the second plenum 732 to a surface of the ceramic plate 708. In this example, the at least one He hole 736 has a diameter of between 0.02 to 0.3 mm. The He supply line hole 716 and the at least one He hole 736 form a helium line, wherein the He supply line hole 716 is a first portion of the He line and the at least one He hole 736 is a second portion of the He line.

The plurality of lumens 728 is located in a way that there is no direct line of sight from the top of the dielectric multilumen plug 720 to the bottom of the dielectric multilumen plug 720. In this embodiment, a central core 740 is bonded in an outer plug 744 to form the dielectric multilumen plug 720. The lumens 728 are formed to pass through the outer plug 744, as shown. A top surface of the central core 740 is spaced apart from a surface of a central cavity in the outer plug 744 to provide a space forming the first plenum 724. Such a configuration allows for the dielectric multilumen plug 720 to be more easily formed. The dielectric multilumen plug 720 is T-shaped. In this embodiment, the top of the T-shaped dielectric multilumen plug 720 is bonded to the top of the T-shaped cavity 718 of the base plate 704. A gap is between the bottom of the T-shaped dielectric multilumen plug 720 and the T-shaped cavity 718 to reduce arcing, as explained in the previous embodiment. In this embodiment, the gap is between 0.1 mm and 1 mm.

FIG. 8 is a schematic cross-sectional view of a spark suppression apparatus in part of an ESC 800 that may be used in another embodiment. In this embodiment, the ESC 800 comprises a base plate 804 bonded to a ceramic plate 808 by a bond layer 812. In this embodiment, the base plate 804 is a conductive metal base plate 804. The base plate 804 has a He supply line hole 816. At an output end of the He supply line hole 816 is a cavity 818. In this embodiment, the cavity 818 is T-shaped. Partially filling the cavity 818 is a dielectric multilumen plug 820. In this embodiment, the dielectric multilumen plug 820 comprises a central core 840 and an outer plug 844. A cylindrical gap 822 is between the central core 840 and the outer plug. The central core has an upside-down T-shape with a flange attached to the outer plug 844. To facilitate He passage into the cylindrical gap 822, there are multiple openings or cutouts in the flange of the central core 840. The cylindrical gap 822 extends to a first plenum 824. Lumens 828 are formed to pass through the outer plug 844, as shown. A top surface of the central core 840 is spaced apart from a surface of a central cavity in the outer plug 844 to provide a space forming the first plenum 824. A plurality of lumens 828 extends from the first plenum 824 to a second plenum 832 adjacent to a surface of the dielectric multilumen plug 820. In this example, the dielectric multilumen plug 820 has 30 to 500 lumens 828, where each lumen 828 has a diameter of between 1 micron and 150 microns. The plurality of lumens 828 may be placed to form concentric circles. On a second side of the second plenum 832, opposite from the first side, is at least one He hole 836 that extends from the second plenum 832 to a surface of the ceramic plate 808. In this example, the at least one He hole 836 has a diameter of between 0.2 to 0.3 mm. A slit 848 at the bottom of the central core 840 allows gas to pass from the He supply line hole 816 to the cylindrical gap 822.

The dielectric multilumen plug 820 is T-shaped. In this embodiment, the top of the T-shaped dielectric multilumen plug 820 is bonded to the top of the T-shaped cavity 818 of the base plate 804. A gap is between the bottom of the T-shaped dielectric multilumen plug 820 and the T-shaped cavity 818 to reduce arcing. In this embodiment, the gap is between 0.1 mm and 1 mm. The lumens 828 are be located away from the cylindrical gap 822 to avoid a direct line of sight from the top of the dielectric multilumen plug 820 to its bottom.

FIG. 9 is a schematic cross-sectional view of a spark suppression apparatus in part of an ESC 900 that may be used in another embodiment. In this embodiment, the ESC 900 comprises a base plate 904 bonded to a ceramic plate 908 by a bond layer 912. In this embodiment, the base plate 904 is a conductive metal base plate 904. The base plate 904 has a He supply line hole 916. At an output end of the He supply line hole 916 is a cavity 918. In this embodiment, the cavity 918 is T-shaped. Partially filling the cavity 918 is a dielectric multilumen plug 920. A cylindrical groove 922 is formed in the dielectric multilumen plug 920 extending from the bottom of the dielectric multilumen plug 920 towards the top of the dielectric multilumen plug 920. The cylindrical groove 922 forms a first plenum. Lumens 928 are formed to pass from the cylindrical groove 922 to the top of the dielectric multilumen plug 920 and to a second plenum 932 adjacent to a surface of the dielectric multilumen plug 920. In this example, the dielectric multilumen plug 920 has 30 to 500 lumens 928, where each lumen 928 has a diameter of between 1 micron and 150 microns. The plurality of lumens 928 may be placed to form concentric circles. On a second side of the second plenum 932, opposite from the first side, is at least one He hole 936 that extends from the second plenum 932 to a surface of the ceramic plate 908. In this example, the at least one He hole 936 has a diameter of between 0.02 to 0.3 mm. The He supply line hole 916 and the at least one He hole 936 form a helium line, wherein the He supply line hole 916 is a first portion of the He line and the at least one He hole 936 is a second portion of the He line.

The dielectric multilumen plug 920 is T-shaped. In this embodiment, the top of the T-shaped dielectric multilumen plug 920 is bonded to the top of the T-shaped cavity 918 of the base plate 904. A gap is between the bottom of the T-shaped dielectric multilumen plug 920 and the T-shaped cavity 918 to reduce arcing. In this embodiment, the gap is between 0.1 mm and 1 mm.

Other embodiments may have different combinations of various features of the different embodiments. For example, a dielectric multilumen plug, such as the second dielectric multilumen plug 528 and third plenum 532 of the embodiment shown in FIG. 5 may be formed in the ceramic plates 608, 708, 808, and 908 of the embodiments shown in FIG. 6, FIG. 7, FIG. 8, and FIG. 9.

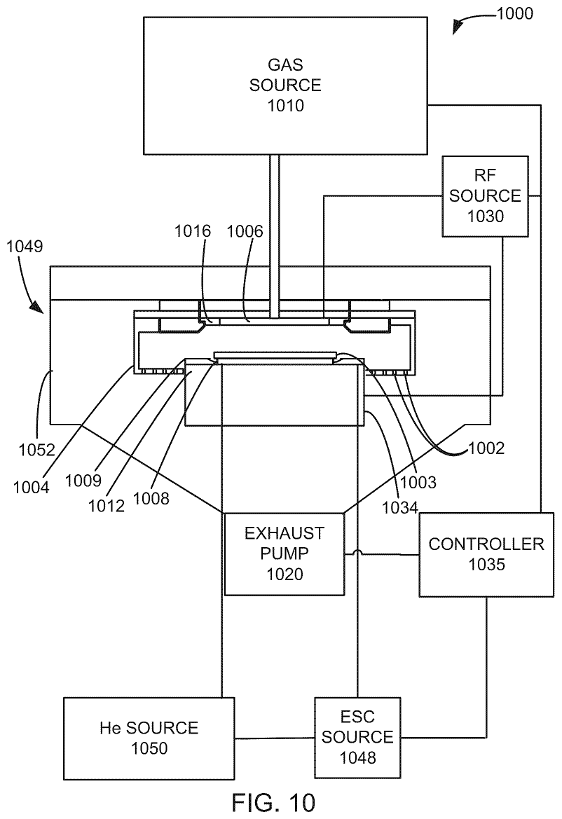

FIG. 10 is a schematic view of an embodiment of a semiconductor processing chamber 1000 that may be used for processing a semiconductor wafer. In one or more embodiments, a semiconductor processing chamber 1000 comprises a gas distribution plate 1006 providing a gas inlet and an electrostatic chuck (ESC) 1008, within an etch chamber 1049, enclosed by a chamber wall 1052. Within the etch chamber 1049, a wafer 1003 is positioned over the ESC 1008. The ESC 1008 is a wafer support. An edge ring 1009 surrounds the ESC 1008. An ESC source 1048 may provide a bias to the ESC 1008. A gas source 1010 is connected to the etch chamber 1049 through the gas distribution plate 1006. An ESC He source 1050 is connected to the ESC 1008.

A radio frequency (RF) source 1030 provides RF power to a lower electrode, an upper outer electrode 1016, and an upper inner electrode. In this embodiment, the ESC 1008 is the lower electrode and the gas distribution plate 1006 is the upper inner electrode. In an exemplary embodiment, 400 kilohertz (kHz), 60 megahertz (MHz), 2 MHz, 13.56 MHZ, and/or 27 MHz power sources make up the RF source 1030 and the ESC source 1048. In this embodiment, one generator is provided for each frequency. In other embodiments, the generators may be separate RF sources, or separate RF generators may be connected to different electrodes. Other arrangements of RF sources and electrodes may be used in other embodiments. In other embodiments, an electrode may be an inductive coil.

A controller 1035 is controllably connected to the RF source 1030, the ESC source 1048, an exhaust pump 1020, and the gas source 1010. A high flow liner 1004 is a liner within the etch chamber 1049. The high flow liner 1004 in this embodiment is a C-shroud and confines gas from the gas source and has slots 1002. The high flow liner 1004 allows for a controlled flow of gas to pass from the gas source 1010 to the exhaust pump 1020.

During processing, He gas may be provided from the ESC He source 1050 to the backside of the ESC 1008 to provide heat transfer. The RF source 1030 provides power to form a plasma. The plasma may cause arcing. The arcing could pass towards the He source and damage the ESC 1008. The above embodiment reduces arcing and therefore reduces ESC 1008 damage.

While this disclosure has been described in terms of several embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A spark suppression apparatus for a wafer backside cooling line in an electrostatic chuck in a plasma processing chamber, the spark suppression apparatus comprising a dielectric multilumen plug in the wafer backside cooling line, wherein the dielectric multilumen plug has a plurality of lumens, wherein the wafer backside cooling line has a first portion on a first side of the dielectric multilumen plug and a second portion on a second side of the dielectric multilumen plug, and wherein the lumens of the plurality of lumens are not placed along a direct line of sight between the first portion of the wafer backside cooling line and the second portion of the wafer backside cooling line, wherein the dielectric multilumen plug is T-shaped, and wherein the dielectric multilumen plug is mounted in a T-shaped cavity, and wherein the dielectric multilumen plug does not extend to a bottom of the T-shaped cavity.

2. The spark suppression apparatus, as recited in claim 1, further comprising a first plenum on the first side of the dielectric multilumen plug and a second plenum on the second side of the dielectric multilumen plug, the second side being opposite the first side, wherein the plurality of lumens extend from the first plenum to the second plenum.

3. The spark suppression apparatus, as recited in claim 1, wherein the dielectric multilumen plug further comprises a solid core between the first portion of the wafer backside cooling line and the second portion of the wafer backside cooling line, and wherein the plurality of lumens surround the solid core.

4. The spark suppression apparatus, as recited in claim 2, further comprising a dielectric plug adjacent to the second plenum spaced on an opposite side of the second plenum from the dielectric multilumen plug.

5. The spark suppression apparatus, as recited in claim 4, wherein the dielectric plug is a porous dielectric plug or comprises a second plurality of lumens extending through the dielectric plug.

6. The spark suppression apparatus, as recited in claim 2, wherein the dielectric multilumen plug extends into at least one of the first plenum and the second plenum.

7. The spark suppression apparatus, as recited in claim 1, wherein the dielectric multilumen plug is a dielectric ceramic plug.

8. The spark suppression apparatus, as recited in claim 1, wherein the dielectric multilumen plug is bonded to the electrostatic chuck.

9. The spark suppression apparatus, as recited in claim 1, wherein a top of the dielectric multilumen plug is bonded to the top of the T-shaped cavity and further comprising a gap between the T-shaped cavity and the dielectric multilumen plug below the top of the T-shaped cavity, wherein the dielectric multilumen plug does not contact the T-shaped cavity below the top of the T-shaped cavity.

10. The spark suppression apparatus, as recited in claim 1, wherein the electrostatic chuck comprises a base plate, a ceramic plate, a bond layer between the base plate and the ceramic plate, wherein the spark suppression apparatus, further comprises a first plenum between the base plate and the ceramic plate, wherein the first plenum is adjacent to the dielectric multilumen plug, and wherein the plurality of lumens extend to the first plenum.

11. The spark suppression apparatus, as recited in claim 10, wherein the dielectric multilumen plug is bonded to the base plate or the ceramic plate.

12. A spark suppression apparatus for a wafer backside cooling line in an electrostatic chuck in a plasma processing chamber, the spark suppression apparatus comprising a T-shaped dielectric plug in the wafer backside cooling line, wherein the T-shaped dielectric plug is mounted in a T-shaped cavity, and wherein the T-shaped dielectric plug does not extend to a bottom of the T-shaped cavity.

13. The spark suppression apparatus, as recited in claim 12, wherein the electrostatic chuck comprises a base plate, a ceramic plate, a bond layer between the base plate and the ceramic plate, wherein the spark suppression apparatus, wherein the T-shaped dielectric plug extends from the bond layer into the base plate, wherein the T-shaped dielectric plug has a first end adjacent to the bond layer and a second end spaced apart from the first end, wherein the second end does not contact the base plate.

14. The spark suppression apparatus, as recited in claim 12, wherein a top of the T-shaped dielectric plug is bonded to the top of the T-shaped cavity.

15. The spark suppression apparatus, as recited in claim 12, further comprising a gap between the T-shaped cavity and the T-shaped dielectric plug below a top of the T-shaped cavity.

16. The spark suppression apparatus, as recited in claim 15, wherein the T-shaped dielectric plug does not contact the T-shaped cavity below the top of the T-shaped cavity.
